(19) United States
(12) Patent Application Publication
(10) Pub. No.: US 2010/0174501 A1
(43) Pub. Date: Jul. 8, 2010

(54) Method, Apparatus And Computer Program For Conserving Battery Charge

(75) Inventor: Srikanth Myadam, Secunderabad (IN)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/652,443

(22) Filed: Jan. 5, 2010

(30) Foreign Application Priority Data
Jan. 5, 2009 (GB) 0900075.3

(51) Int. Cl. G01R 31/36

(52) U.S. Cl. 702/63

(57) ABSTRACT

A method comprising determining a remaining electrical charge in a battery of a apparatus using a charge conserving system of the apparatus. The apparatus includes a plurality of hardware and/or software components. The charge conserving system is capable of defining one or a number of charge thresholds. The or each charge threshold corresponds to a quantity of remaining electrical charge in the battery. The method also includes broadcasting a charge status notification, using the charge conserving system, to at least one of a predefined group of the hardware and/or software components when the remaining electrical charge in the battery falls below the or each charge threshold.

### RELATED APPLICATION

The present application claims priority to Great Britain Patent Application No. 0900075.3 filed Jan. 5, 2009, the contents of which are incorporated by reference herein.

### TECHNICAL FIELD

The present invention relates to a method, apparatus and computer program for conserving battery charge. In some embodiments it relates to conserving battery charge in an apparatus by limiting apparatus capabilities.

### BACKGROUND

Mobile communication devices typically comprise a battery which delivers electrical charge to the device. From time to time the battery requires recharging and in order to effect recharging the device must be connected to an external electrical supply, such as a DC mains adapter connected to a mains supply. Prolonging the period of time during which the device can operate without having to be connected to an external electrical supply can be advantageous.

### SUMMARY OF EXAMPLES OF THE INVENTION

A first aspect of the invention provides a method, comprising: determining a remaining electrical charge in a battery of an apparatus using a charge conserving system of the apparatus, said apparatus comprising a plurality of hardware and/or software components, said charge conserving system being capable of defining one or a number of charge thresholds, the or each charge threshold corresponding to a quantity of remaining electrical charge in the battery, and broadcasting a charge status notification, using the charge conserving system, to at least one of a predefined group of the hardware and/or software components when the remaining electrical charge in the battery falls below the or each charge threshold.

A second aspect of the invention provides an apparatus, comprising at least one processor; and at least one memory including computer program code, the at least one memory and the computer program code configured to, with the at least one processor, cause the apparatus to perform at least the following: determine a remaining electrical charge in a battery using a charge conserving system, said charge conserving system being capable of defining one or a number of charge thresholds, the or each charge threshold corresponding to a quantity of remaining electrical charge in the battery, and broadcast a charge status notification, using the charge conserving system, to at least one of a predefined group of hardware and/or software components when the remaining electrical charge in the battery falls below the or each charge threshold.

The battery and the hardware and/or software components may form part of the apparatus, or they may be part of one or more further apparatuses.

A third aspect of the invention provides a computer program product comprising a computer readable medium bearing computer program code embodied therein for use with a computer, the computer program code comprising: code for determining a remaining electrical charge in a battery of an apparatus using a charge conserving system, said apparatus comprising a plurality of hardware and/or software components, said charge conserving system being capable of defining one or a number of charge thresholds, the or each charge threshold corresponding to a quantity of remaining electrical charge in the battery, and code for broadcasting a charge status notification, using the charge conserving system, to at least one of a predefined group of the hardware and/or software components when the remaining electrical charge in the battery falls below the or each charge threshold.

A charge status notification may comprise an indication of a quantity of remaining electrical charge in the battery at a corresponding broadcast time.

The charge conserving system can define a plurality of charge thresholds, and can be capable of broadcasting a charge status notification to a different set of the predefined group when the remaining electrical charge in the battery falls below each different charge threshold.

The or each hardware and/or software components may optionally be capable of reducing its electrical charge demand on the battery on receipt of a charge status notification broadcast when the remaining electrical charge in the battery falls below a charge threshold, in order to conserve battery charge.

The method may further comprise broadcasting a charge state notification, using the charge conserving system, to at least one of the predefined group of the hardware and/or software components when the remaining electrical charge in the battery rises above the or each charge threshold.

The charge conserving system could define a plurality of charge thresholds, and be capable of broadcasting a charge status notification to a different set of the predefined group when the remaining electrical charge in the battery rises above each different charge threshold.

The or each hardware and/or software components may be capable of increasing its electrical charge demand on the battery on receipt of a charge status notification broadcast when the remaining electrical charge in the battery rises above a charge threshold, in order to restore the apparatus to a previous state of operation.

The method could further comprise receiving, at the charge conserving system, registration from each hardware and/or software components, and defining, using the charge conserving system, at least part of the predefined group in dependence on which hardware and/or software components it has received registration from.

The method could further comprise instructing at least one of the predefined group to shutdown when the remaining electrical charge in the battery falls below the or each charge threshold, using a decision engine of the charge conserving system. The charge conserving system could define a plurality of charge thresholds, and the decision engine could be capable of instructing a different set of the predefined group to shutdown when the remaining electrical charge in the battery falls below each different charge threshold.

The method could also comprise instructing at least one of the predefined group to start-up when the remaining electrical charge in the battery rises above the or each charge threshold, using the decision engine. The charge conserving system could define a plurality of charge thresholds, and the decision engine could be capable of instructing a different set of the predefined group to start-up when the remaining electrical charge in the battery rises above each different charge threshold.

The charge conserving system may broadcast a charge status notification to at least one hardware and/or software components when the remaining electrical charge in the battery crosses one of the plurality of charge thresholds, and the decision engine may start-up or shut-down the at least one hardware and/or software components when the remaining electrical charge in the battery crosses a different one of the plurality of charge thresholds.

The decision engine could instruct a hardware and/or software components to shutdown only if it is not required by the apparatus to perform a telephony function.

The charge conserving system may be capable of defining at least part of the predefined group in dependence on an input received from a user of the apparatus.

The charge conserving system could be capable of defining at least part of any set of the predefined group in dependence on an input received from a user of the apparatus.

The method could further comprise setting the quantity of remaining electrical charge in the battery which corresponds to the or each charge threshold in dependence on an input received from a user of the apparatus, using the charge conservation system.

The hardware and/or software components of the predefined group may be such that they are not required by the apparatus to perform a telephony function.

### BRIEF DESCRIPTION OF THE DRAWINGS

Example embodiments of the present invention will now be described by reference to the accompanying drawings, in which:

FIG. 1 is a representation of a smartphone computing device which represents an example of an apparatus on which some embodiments of the invention may be implemented;

FIG. 2 is a schematic illustration of some internal elements of the smartphone of FIG. 1;

FIG. 3 is a schematic illustration of some software components of the smartphone of FIG. 1 when arranged according to a first example embodiment of the present invention;

FIG. 4 is a flow diagram of the operation of the embodiment of FIG. 3;

FIG. 5 is a schematic illustration of some software components of the smartphone of FIG. 1 when arranged according to a second example embodiment of the present invention;

FIG. 6 is a flow diagram of the operation of the embodiment of FIG. 5; and

FIG. 7 is a graphical user interface of the smartphone of FIG. 1 when arranged according to the embodiment of FIG. 5.

### DESCRIPTION OF EXAMPLE EMBODIMENTS

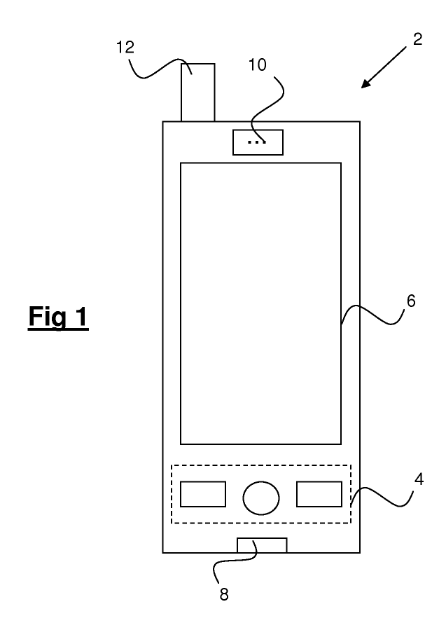

Example embodiments of the present invention will now be described with reference to FIGS. 1 to 7.

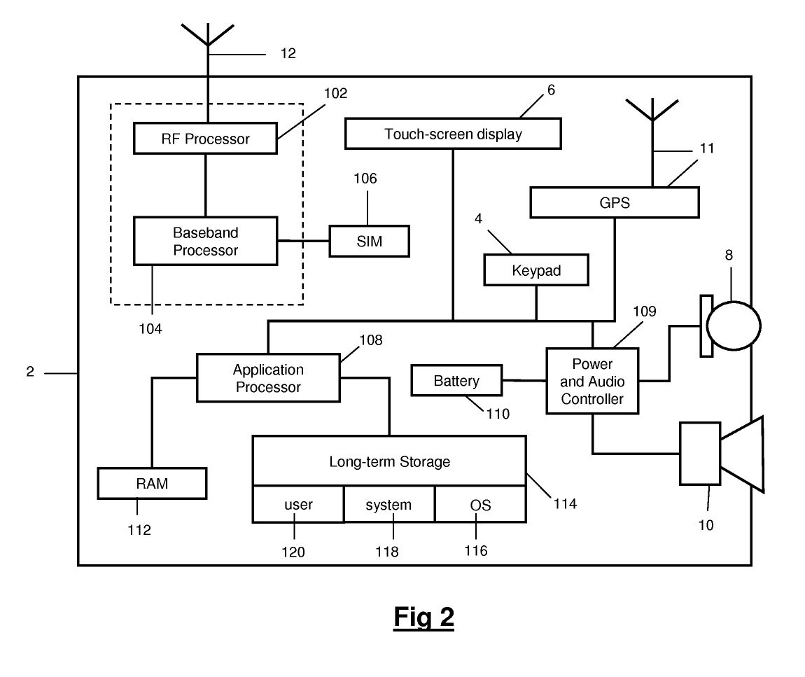

FIGS. 1 and 2 illustrate a smartphone according to an example embodiment of the invention. The smartphone provides the operating environment for this example embodiment, and is one example of an apparatus on which the described embodiments of the invention may be implemented.

The example embodiment of FIG. 1 illustrates a smartphone 2 which comprises a keypad 4, a touch-screen 6, a microphone 8, a speaker 10 and an antenna 12. In this example embodiment, the smartphone 2 is capable of being operated by a user to perform a variety of different functions, such as, for example, hosting a telephone call, sending an SMS message, browsing the internet, sending an email and providing satellite navigation.

The example embodiment of FIG. 2 shows a schematic view of some of the internal hardware elements of the smartphone 2. In this example embodiment, the smartphone 2 comprises hardware to perform telephony functions, together with an application processor and corresponding support hardware to enable the phone to have other functions which may be desired by a smartphone, such as messaging, internet browsing, email functions, satellite navigation and the like. In this example embodiment, the telephony hardware is represented by the RF processor 102 which provides an RF signal to the antenna 12 for the transmission of telephony signals, and the receipt therefrom. Additionally provided in this example embodiment is baseband processor 104, which provides signals to and receives signals from the RF processor 102. In this example embodiment, the baseband processor 104 also interacts with a subscriber identity module 106.

In this example embodiment, the keypad 4 and the touch-screen 6 are controlled by an application processor 108. In this example embodiment, a power and audio controller 109 is provided to supply power from a battery 110 to the telephony subsystem, the application processor 108, and the other hardware. In this example embodiment, the power and audio controller 109 also controls input from the microphone 8, and audio output via the speaker 10. Also provided in this example embodiment is a global positioning system (GPS) antenna and associated receiver element 11 which is controlled by the application processor 108 and is capable of receiving a GPS signal for use with a satellite navigation functionality of the smartphone 2.

In this example embodiment, in order for the application processor 108 to operate, various different types of memory are provided. In this example embodiment, the smartphone 2 includes Random Access Memory (RAM) 112 in communication with the application processor 108 into which data and program code can be written and read from at will. In this example embodiment, code placed anywhere in RAM 112 can be executed by the application processor 108 from the RAM 112. In this example embodiment, RAM 112 represents a volatile memory of the smartphone 2.

In this example embodiment, the smartphone 2 is also provided with a long-term storage 114 connected to the application processor 108. In this example embodiment, the long-term storage 114 comprises three partitions, an operating system (OS) partition 116, a system partition 118 and a user partition 120. In this example embodiment, the long-term storage 114 represents a non-volatile memory of the smartphone 2.

In this example embodiment, the OS partition 116 contains the firmware of the computing device which includes an operating system. In this example embodiment, other computer programs may also be stored on the long-term storage 114, such as application programs, and the like. In particular, application programs which are mandatory to the device, such as, in the case of a smartphone, communications applications and the like can be stored in the system partition 118. In this example embodiment, the application programs stored on the system partition 118 may be those which are bundled with the smartphone by the device manufacturer when the phone is first sold. In this example embodiment, application programs which are added to the smartphone by the user may be stored in the user partition 120.

As stated, the representation of FIG. 2 is schematic. In practise, the various functional components illustrated may be substituted into one and the same component. For example, in some other example embodiments, the long-term storage 114 may comprise NAND flash, NOR flash, a hard disk drive or a combination of these.

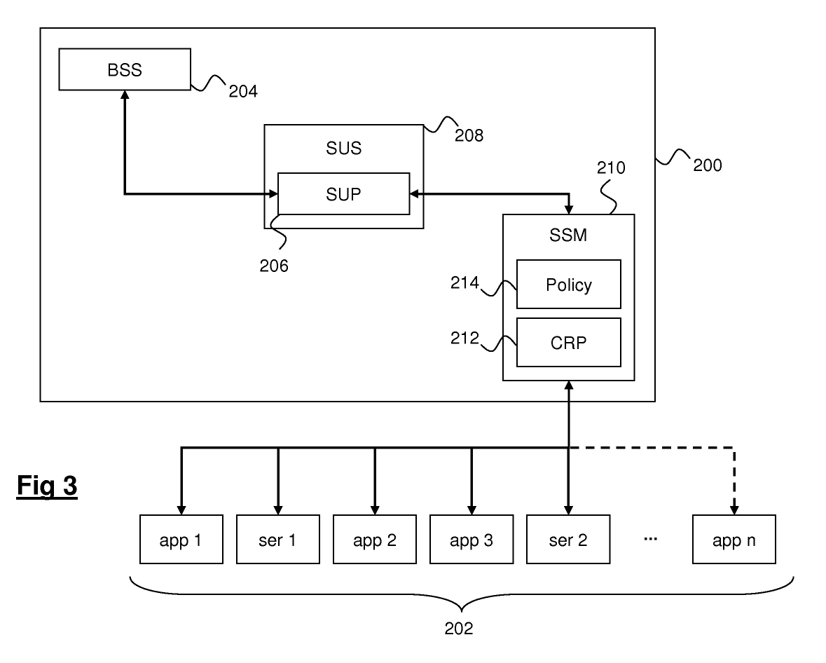

The example embodiment of FIG. 3 shows a schematic diagram of some software components of the smartphone 2. More specifically, in this example embodiment, an operating system 200 is shown in communication with a plurality of other software components 202. In this example embodiment, each of the software components shown on FIG. 3 is stored on a memory of the smartphone 2, for example, as mentioned above, the operating system 200 is stored on the OS partition 116. In this example embodiment, the operating system 200 is provided in order for the application processor 108 to operate, and the operating system 200 is started as soon as the smartphone system 2 is first switched on. In this example embodiment, it is the role of the operating system 200 to manage hardware and software resources of the computing device. These resources include such things as the application processor 108, the RAM 112, and the long-term storage 114. As such, the operating system of the present example embodiment provides a stable, consistent way for software applications running on the smartphone 2 to deal with the hardware resources of the smartphone 2 without the application needing to know all the details of the physical resources available to the hardware.

The example embodiment of FIG. 3 also shows some internal elements (204 to 212) of the operating system 200 which comprise a charge conserving system of the smartphone 2. More specifically, a battery status server (BSS) 204 is connected to a system utility plug-in (SUP) 206 of a system utility server (SUS) 208. In this example embodiment, the SUP 206 is in communication with a system state manager (SSM) 210 which comprises a charge risk property (CRP) 212 and a policy 214. In this example embodiment, the SSM 210 of the operating system 200 is also in communication with the plurality of software components 202.

In this example embodiment, the BSS 204 is capable of determining the remaining charge in the battery 110. In this example embodiment, the BSS 204 is additionally capable of notifying the SUP 206 each time the quantity of remaining charge in the battery 110 changes. For example, battery charge may reduce when it is used up by the various hardware and/or software components of the smartphone 2 or, the charge may increase if the battery 110 is being recharged. In this example embodiment, each time the BSS 204 notifies the SUP 206 that the remaining charge in the battery has changed, the BSS 204 also provides the SUP 206 with an indication of how much charge remains in the battery 110 at the time the notification was formed. In this example embodiment, the quantity of remaining charge in the battery 110 can take any one of a scale of discrete values, wherein a value of ‘100’ indicates that the battery 110 is full of charge whereas a value of ‘0’ indicates that the battery 110 is empty of charge.

In this example embodiment, one of the functions of the SUP 206 is to define a number of charge thresholds. In this example embodiment, each charge threshold corresponds to a specific quantity of remaining charge in the battery 110. In this example embodiment, four charge thresholds are provided having the following names, ‘low’, ‘medium’, ‘high’ and ‘critical’. Further, each charge threshold corresponds to a quantity of remaining charge in the battery 110. In this example embodiment, the four charge thresholds, ‘low’, ‘medium’, ‘high’ and ‘critical’ correspond to the following four values respectively, ‘20’, ‘15’, ‘10’, ‘5’. For example, the BSS 204 may notify the SUP 206 that the quantity of remaining charge in the battery 110 has changed to ‘18’. The value ‘18’ corresponds to the low' charge threshold as the value ‘18’ is less than the low threshold level of ‘20’ but more than the medium threshold level of ‘15’. According to this behaviour the risk that the smartphone 2 will run out of battery charge imminently is said to be ‘low’. However, if the BSS 204 had notified the SUP 206 that the quantity of remaining charge in the battery 110 is ‘2’ the corresponding risk of running out of battery charge imminently would be ‘critical’. Therefore, in this example embodiment, the SUP 206 is capable of determining when the remaining charge of the battery 110 falls below, or rises above, each predefined charge threshold. In this example embodiment, each time the SUP 206 establishes that a charge threshold has been crossed, the SUP 206 makes a request to the SSM 210 to change the value of the CRP 302.

In this example embodiment, one of the roles of the SSM 210 is to manage the state of the smartphone 2 throughout its lifecycle, including during start-up and shutdown. In this example embodiment, the SSM 210 allows software and hardware components of the smartphone 2 to request a change of system state between any of the following possible states, ‘start-up’, ‘shutdown’, ‘normal’ and ‘fail’. In this example embodiment, system states are defined by policies which are stored on the OS partition 116 of the long-term storage 114 and the policies define the set of permissible states and state transitions, and the tasks that are performed when changing the system state. Accordingly, in this example embodiment, the SSM 210 performs many functions in addition to those relating to the present invention. However, according to the operation of the present example embodiment, the SSM 210 receives a request from the SUP 206 to change the value of the CRP 212 each time the SUP 206 establishes that a charge threshold has been crossed.

In this example embodiment, the CRP 212 is a system wide property (also known as a global variable or property) which can take any one of five different values: ‘normal’, ‘low’, ‘medium’, ‘high’ and ‘critical’. In this example embodiment, the value of the CRP 212 at any given time indicates the quantity of remaining charge in the battery 110. Also, in this example embodiment, the values which the CRP 212 can take correspond to the charge thresholds defined by the SUP 206. Accordingly, in this example embodiment, a value of ‘normal’ corresponds to a quantity of remaining charge in the battery within the range ‘100 to 20’; a value of low' corresponds to a quantity of remaining charge in the battery within the range ‘19 to 15’; a value of ‘medium’ corresponds to a quantity of remaining charge in the battery within the range ‘14 to 10’; a value of ‘high’ corresponds to a quantity of remaining charge in the battery within the range ‘9 to 5’; and, a value of ‘critical’ corresponds to a quantity of remaining charge in the battery within the range ‘4 to 0’. As mentioned above, in this example embodiment, a request to change the value of the CRP 212 is sent from the SUP 206 to the SSM 210 each time the remaining charge in the battery 110 crosses one of the charge thresholds.

In this example embodiment, the policy 214 of the SSM 210 defines what conditions must be true in order that the value of the CRP 212 can be validly changed. For example, certain servers may have insufficient security privileges to validly request that the value of the CRP 212 is changed, while other servers may be authorised to request this change.

In this example embodiment, the CRP 212 operates according to a ‘publish and subscribe’ mechanism. According to the publish and subscribe mechanism one or a number of ‘publishers’ are defined with respect to the CRP 212. In this example embodiment, each publisher has the authority to change the value of the CRP 212 according to rules defined by the policy 214. For example, only a publisher with sufficient security privileges may be permitted to change the value of the CRP 212. In this example embodiment, the SUP 206 is a publisher in respect of the CRP 212. In this example embodiment, the publish and subscribe mechanism also provides for the definition of one or a number of ‘subscribers’ with respect to the CRP 212. In this example embodiment, each subscriber is a software component which has actively registered with the SSM 210 to receive a notification from the SSM 210 each time the value of the CRP 212 changes. In this example embodiment, each one of the plurality of software components 202 is eligible to become a subscriber if it registers with the SSM 210. According to the publish and subscribe mechanism of the present example embodiment, a charge status notification is broadcast by the SSM 210 to each subscriber each time the value of the CRP 212 changes, and included in each notification is an indication of the new value that the CRP 212 has changed to.

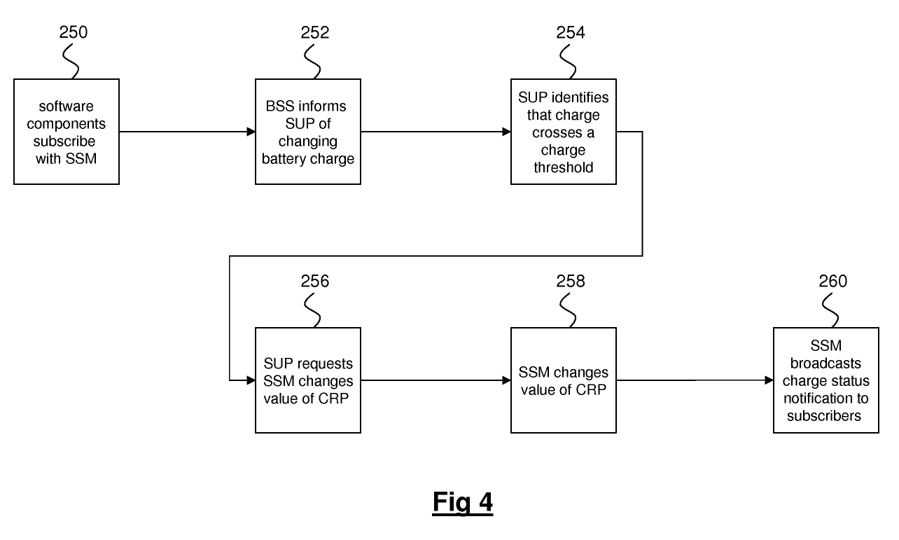

The above described operation of the present example embodiment is represented in the flow diagram of FIG. 4. At block 250 of FIG. 4, one or more of the plurality of software components 202 actively registers with the SSM 210 to become a subscriber and thereby to receive broadcast notifications relating to the CRP 212 system-wide property. In this example embodiment, during operation of the smartphone 2, the BSS 204 is continuously aware of the remaining charge in the battery 110. At block 252, each time the quantity of remaining charge changes the BSS 204 informs the SUP 206 of the change and provides the SUP 206 with an indication of how much charge remains in the battery 110 at that time. In this example embodiment, the SUP 206 defines a number of charge thresholds, each of which correspond to a quantity of remaining charge in the battery 110. At block 254, as the SUP 206 is kept informed by the BSS 204 of how much charge remains in the battery 110, the SUP 206 is capable of determining when the quantity of remaining charge in the battery 110 crosses a charge threshold. In this example embodiment, the SUP 206 is capable of determining both when the quantity of remaining charge in the battery 110 falls below a charge threshold and when it rises above a charge threshold. At block 256, each time the SUP 206 determines that a charge threshold has been crossed it makes a request to the SSM 210 that the value of the CRP 212 is changed appropriately. At block 258, as the SUP 206 has sufficient access privileges according to the policy 214 to change the value of the CRP 212, on receipt of the request from the SUP 206, the SSM 210 updates the value of the CRP 212 as requested. At block 260, once the SSM 210 changes the value of the CRP 212, the SSM 210 automatically broadcasts a charge status notification, containing an indication of the new value of the CRP 212, to each software component that is a registered subscriber. It should be noted that although in this described embodiment notifications are sent each time the charge level crosses a threshold, this is only one implementation choice and alternatives are possible within the scope of embodiments of the invention. For example a hysteresis could be defined, or some threshold notifications could be disabled for some or all registered components.

It is an advantage of this example embodiment that charge status notifications are automatically broadcast to software components when the battery charge level crosses each charge threshold, while moving from a state of higher charge to a state of lower charge. This operation is in contrast to a situation in which components repeatedly request battery status information to keep up-to-date with a current charge status of the battery. This example may in some circumstances be preferable over this latter situation because it can provide a conservation of battery charge resulting from a reduction in the amount of processing required to operate.

It is an advantage of this example embodiment that different software components can be notified of dwindling battery charge when different quantities of charge remain in the battery. According to this advantage, the level of battery charge when each component is notified can be set according to the battery charge demand of the component.

It is an advantage of this example embodiment that a software component can subscribe with the SSM 210 to automatically receive charge status notifications containing an indication of the quantity of remaining charge in the battery 110. In this example embodiment, as a number of charge thresholds and corresponding values of the CRP 212 are provided it is a further advantage that a subscribed software component is notified in a ‘staged’ manner, rather than receiving only a single notification just before battery charge runs out. According to this example operation, each subscribed software component is given a freedom to decide if, and how, it will adjust its demand on the battery 110, for example, to preserve telephony functions. For example, a software component whose sole function is to assist in the provision of a satellite navigation function receives a notification from the SSM 210 that the CRP 212 has changed to a ‘low’ value. In these circumstances the software component may choose to either shutdown or cease operating. Further, a different software component whose sole function is to assist in the provision of a multi-media messaging (MMS) functionality may choose not to shutdown or cease operation until the CRP 212 has dropped to a ‘medium’ value. Further still, another different software component whose function is to assist in the provision of a short message service (SMS) functionality may never choose to shutdown or cease operation, even when the CRP 212 has dropped to a ‘critical’ value. According to this example, the smartphone's SMS messaging telephony function can operate for longer, as less battery charge is used up compared with satellite navigation and MMS messaging functionalities.

It is an advantage of this example embodiment that subscribed software components automatically receive broadcast notifications whenever the CRP value changes. Therefore, subscribed software components are notified whenever the charge risk state changes. Accordingly, in this example embodiment, software components which are interested in reducing their charge demand on the battery during periods when the remaining charge in the battery is low do not need to constantly request the level of remaining battery charge. Instead, the software components can rely on receiving a notification which will be broadcast automatically. This can represent a reduction in the level of processing which needs to be performed by the smartphone 2 and therefore, this operation can aid in prolonging the period of time during which the battery 110 alone can power the smartphone 2 to perform certain functions such as telephony functions.

It is an advantage of this example embodiment that software components which are used to perform a non-telephony function can receive notifications and thereby choose whether or not to limit or cease their demand on battery charge. Accordingly, in one example battery charge can be conserved for use by software components which are used to perform telephony functions, which may be considered an important aspect of the operation of a device.

It is an advantage of this example embodiment that charge thresholds are defined as ‘two-way’ thresholds. More specifically, notifications may also be sent when the battery charge level crosses a threshold while moving from a lower charge state to a higher charge state. Therefore, notified components which may have halted their operation when the charge level fell below a threshold can now be re-started as soon as charge level rises above the threshold. Accordingly, the device can be restored to a previous state of operation.

It is an advantage of this example embodiment that multiple charge thresholds can be defined so that hardware and/or software components can be notified of rising battery charge in a staged manner. Additionally, it is also an advantage that different hardware and/or software components can be notified of increasing battery charge when the charge rises to different levels. According to this latter advantage, the level of battery charge when each component is notified can be set according to the battery charge demand of the component. In some embodiments is may be desirable to define fewer or more thresholds than in the described example.

It is an advantage of this example embodiment that hardware and/or software components which chose to limit or cease their operation when battery charge was dwindling, can receive notifications and, on receipt of those notifications, choose to resume normal operation. Accordingly, the device can be automatically restored to a previous state of operation.

It is an advantage of this example embodiment that individual components can choose to receive notifications of falling and rising battery charge. Accordingly, each notified component is free to decide if, and how, to react to either falling or rising battery charge. Such reactions may be defined by software or hardware controlling the operation of a component. The reactions may be static, in the sense that the component reacts to a given change in charge status in the same way regardless of other aspects of the device's operation, or they may be dynamic, in the sense that the component can react differently to the same charge status change in dependence on other aspects of the device's operation, such as whether a given component is currently running

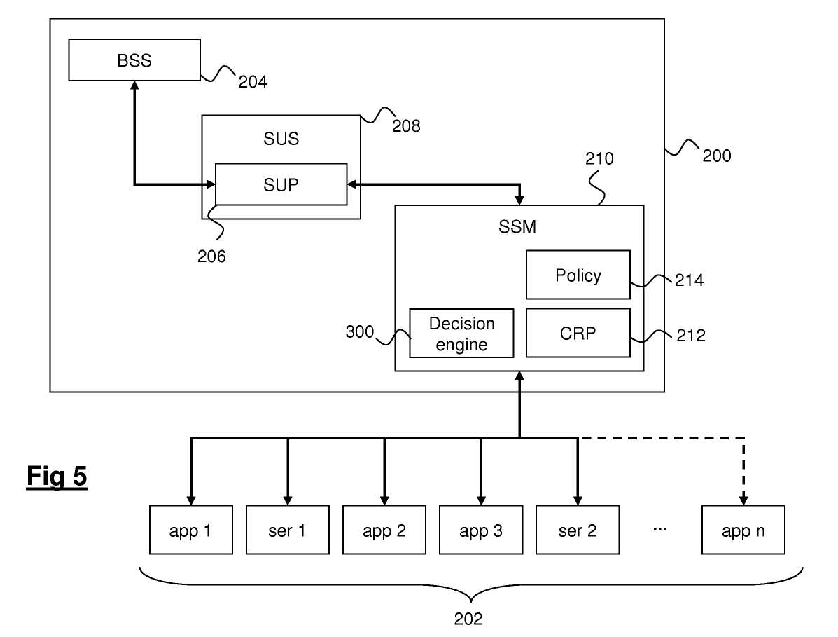

Modifications can be made to the charge conserving system of the present example embodiment to create alternative example embodiments. FIG. 5 shows a schematic diagram of an alternative example embodiment. A difference between the previous example embodiment and the alternative example embodiment is the introduction of a decision engine 300 within the SSM 210. The alternative example embodiment comprises the same functionality as the previous example embodiment and additionally comprises a further functionality. In the alternative example embodiment, the further functionality is provided by the decision engine 300 and comprises an ability to instruct each of the plurality of software components 202 to shutdown in dependence on the value of the CRP 212, for example, in order to prolong the period of time during which the smartphone 2 can perform telephony functions. Also, in this alternative example embodiment, the further functionality comprises an ability to instruct each of the plurality of software components 202 to start-up in dependence on the CRP value, for example, in order to restore the smartphone 2 to a previous state of operation once charge in the battery 110 is restored.

More specifically, in this example embodiment, the decision engine 300 comprises a number of ‘sets’ or ‘lists’ which define which software components are permitted to operate at particular charge risk states, wherein the charge risk states are defined by the value of the CRP 212. Therefore, in this example embodiment, the decision engine 300 comprises one list for each of the following charge risk states, ‘normal’, ‘low’, ‘medium’, ‘high’ and ‘critical’. For example, the decision engine 300 contains a list which defines which software components are permitted to operate in a ‘medium’ charge risk state. In this example embodiment, the purpose of the lists is to ensure that as the charge in the battery 110 begins to run out, the software components which are permitted to operate are those which are necessary for the smartphone 2 to perform certain functions, for example, telephony functions. In this example embodiment, as multiple charge thresholds are provided the shutdown of software components which are not associated with those certain functions can be performed in a staged manner. Also, as the alternative example embodiment also comprises the functionality of the previous example embodiment, some software components can be notified of the current charge state rather than being instructed to shutdown. By instructing shutdown, the alternative example embodiment is able to control which software components operate. By notifying of a change in charge risk state, the alternative example embodiment is able to provide individual software components with a freedom to decide how to respond to depleting charge in the battery 110.

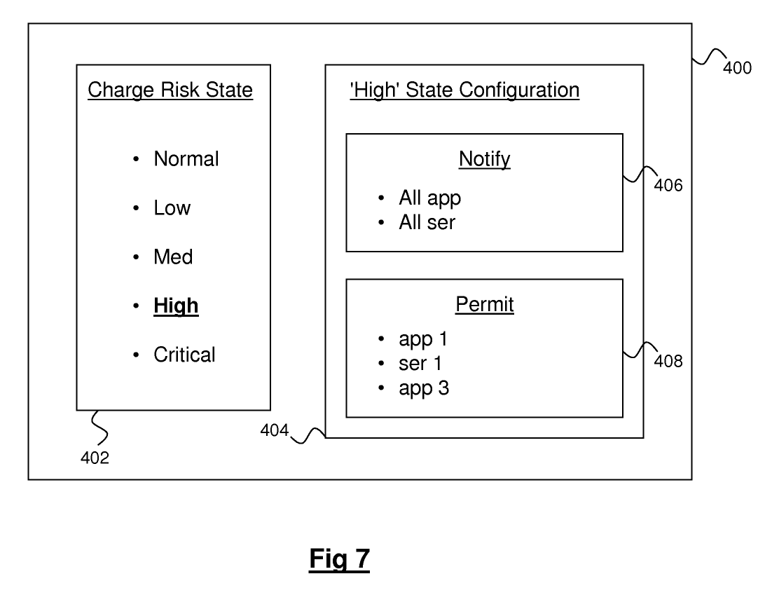

According to the alternative example embodiment the contents of the sets or lists of the decision engine 300 can be defined in one of two ways. Firstly, certain list entries are defined by the system and, as such, are hard-coded into the decision engine 300. Secondly, other list entries can be defined by a user of the smartphone 2, such as, for example, when the smartphone 2 is being configured by a user after the user has purchased the smartphone 2. As seen more particularly in the example embodiment of FIG. 7, the decision engine 300 provides a graphical user interface 400 which is suitable for display on the touch-screen 6 of the smartphone 2. In this example embodiment, the box 402 provides a list for each charge risk state, ‘normal’, ‘low’, ‘medium’, ‘high’ and ‘critical’. In this example embodiment, each charge risk state in the box 402 is an option which can be selected by the user of the smartphone 2 using the touch-screen 6 together with an associated pointing instrument (e.g. a finger or a stylus). In this example embodiment, upon selection of one of the charge risk states, the box 404 appears. In this example embodiment, the box 404 contains the settings relevant to the charge risk state which has been selected. It can be seen on the example embodiment of FIG. 7 that the ‘high’ state has been selected as the word ‘high’ in box 402 is emboldened and underlined. Also, the title of the box 404 refers to the ‘high’ state.

In this example embodiment, the box 404 comprises two nested boxes 406 and 408. In this example embodiment, the box 406 contains a list of the software components that shall be notified each time the charge risk state changes from the ‘medium’ state to the ‘high’ state. In this example embodiment, the box 408 contains a list of the software components that shall be permitted to operate in the ‘high’ state. Therefore, when the value of the CRP 212 changes from ‘medium’ to ‘high’ all software components apart from those listed in box 408 could be instructed to shutdown by the decision engine 300. In this example embodiment, the boxes 406 and 408 can optionally include software components designated by the user and those hard-coded into the decision engine 300, or only those designated by the user. Additionally, in this example embodiment, some software components in the box 406 can optionally be designated as a ‘two-way’ software component. If a software component is designated as a two-way element in the box 406, it is notified when the charge risk state changes to a ‘high’ stage from a ‘critical’ state as well as a ‘medium’ state. In other words, notifications are also sent when the remaining charge in the battery 110 rises above a charge threshold as well as when charge drops below a charge threshold. Also, in this example embodiment, a ‘two-way’ configuration can optionally be provided in relation to the box 408. Accordingly, software components which are instructed to shutdown when charge falls below a charge threshold are instructed to start-up when charge rises back above the charge threshold. According to the two-way configuration, the smartphone 2 can be restored to a previous state of operation once the battery 110 has been re-charged. It should be noted that many changes may be made to this user interface within the scope of embodiments of the invention. For example a limited number of options may be provided to a user to simplify setting the charge state change operation of the device.

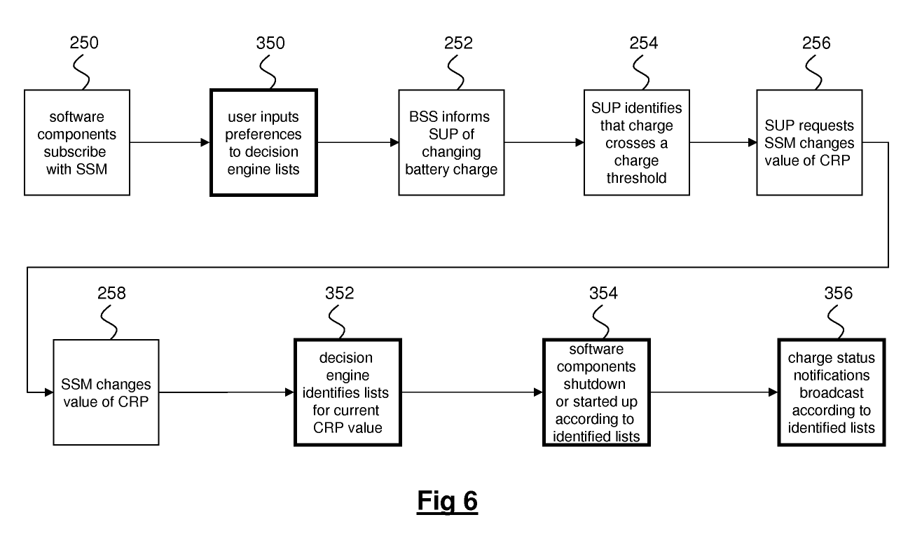

The above-described operation of the alternative example embodiment is illustrated in the flow diagram of FIG. 6. In blocks 250 to 258 of FIG. 6, the operation of the alternative example embodiment is the same as described above with reference to the previous example embodiment and FIG. 4. However, FIG. 6 also comprises new blocks 350 to 356. At new block 350, a user of the smartphone 2 inputs preferences into the lists of the decision engine 300. In this example embodiment, a list defines which software components may operate, and which components are notified, for a particular value of the CRP 212, for example the lists which would appear in box 406 and 408. At new block 352, the decision engine 300 identifies the lists corresponding to the new value of the CRP 212. At new block 354, if the battery charge is falling, the decision engine 300 shuts down those software components which are operational and are not present in the box 408 list identified at block 352. Alternatively, if the battery charge is rising, for entries in the box 408 list which have a two-way configuration and relate to a software component which is not operational, the decision engine starts-up that software component if it was shut-down the last time the CRP value fell below the current CRP value. At block 356, charge status notifications are broadcast to all software components which are present in the box 406 list identified at block 352.

According to the alternative example embodiment, some software components of the smartphone could be notified for some charge risk states, and shutdown for another charge risk state. In an example, a software component whose sole function is related to a satellite navigation function of the smartphone 2 may be notified when the charge risk state changes to a ‘low’ state and then shutdown or prevented from operating at a ‘medium’ state, a ‘high’ state or a ‘critical’ state. More specifically, this component features in box 406 (FIG. 7) for the ‘low’ state, and is absent from box 408 for the ‘medium’, ‘high’ or ‘critical’ states. In a further example, a software component whose sole function is related to an MMS function may be notified when the charge risk state changes to a ‘low’ or a ‘medium’ state and then shutdown or prevented from operating at anything below a ‘medium’ state. More specifically, this component features in box 406 for the ‘low’ and ‘medium’ states, and is absent from box 408 for the ‘high’ and ‘critical’ states. Further still, a software component whose function is related to an SMS function may not be notified or shutdown regardless of the charge risk state. More specifically, this component is absent from box 406 and box 408 for each state.

It is an advantage of the alternative example embodiment that the charge conserving system can decide how certain software components will react to dwindling battery charge. Further, it is an advantage of this example embodiment that the system can actively cause components which are not related to telephony functions to shutdown so that battery charge is conserved for components which are related to telephony functions. Accordingly, the period during which the device can perform telephony functions using battery charge alone may be prolonged. In an example, the smartphone 2 could further comprise a removable memory card for storing software components, such as user installed software applications. According to this example, when the ‘high’ charge risk state is entered the charge conservation system is configured to instruct software components stored on the removable memory card to shutdown. Additionally or alternatively, the charge conservation system could instruct software components stored on the system partition 118 and/or the user partition 120 (i.e. not on the OS partition 116) to shutdown when the ‘high’ charge risk state is entered. Such an arrangement could prolong the period during which the device could perform telephony functions if the removable memory card, the system partition 118 and the user partition 120 contain software components which are related to non-telephony functions.

It is an advantage of the alternative example embodiment that multiple charge thresholds may be defined so that software components can be shutdown in a staged manner, with respect to dwindling battery charge. Additionally, it is also an advantage of this example embodiment that different software components can be shutdown when the charge drops to different levels. According to this latter advantage, the level of battery charge when each component is shutdown can be set according to the battery charge demand from the component.

It is an advantage of the alternative example embodiment that charge thresholds may be defined as ‘two-way’ thresholds. Therefore, components can be started-up when the battery charge level rises above a threshold, as well as being shutdown when the charge level falls below the threshold. Accordingly, the device can be automatically restored to a previous state of operation.

It is an advantage of the alternative example embodiment that multiple charge thresholds may be defined so that software components can be started-up in a staged manner, with respect to rising battery charge. Additionally, it is also an advantage of this example embodiment that different hardware and/or software components can be started-up when the charge rises to different levels. According to this latter advantage, the level of battery charge when a component is started-up can be set according to the battery charge demand from the component.

It is an advantage of the alternative example embodiment that a user of the device can choose which software components are instructed to shutdown and/or receive automatically broadcast notifications. Accordingly, the user can define how components are prioritised when battery charge is limited and may adapt these priorities according to personal usage of the device. Also, the user can define which components are started up and therefore how the device is restored when the battery is recharged. For example, one user may choose to retain an internet browsing functionality at the expense of an MP3 or telephony functionality, whereas a different user may choose to prioritise a telephony functionality above all other device functionalities.

It is an advantage of the alternative example embodiment that a user can define which specific components are notified or shutdown when the remaining charge in the battery falls below each different charge threshold. It is also an advantage of this example embodiment that the user can define which specific components are notified or started-up when the remaining charge in the battery rises above each different charge threshold. According to this embodiment, the user can prioritise certain components over other components. For example, a user may choose to shutdown or notify an MP3 functionality when battery charge is half full, whereas the user may choose to shutdown or notify a satellite navigation functionality when battery charge is quarter full. A different user may choose to shutdown or notify these functionalities in the opposite order.

It is an advantage of the alternative example embodiment that non-telephony functions can be notified or shutdown to conserve battery charge and that telephony functions may therefore be able to operate for a longer period of time using battery charge alone.

It is an advantage of the alternative example embodiment that software components of the smartphone 2 can be notified when charge in the battery 110 rises above each charge threshold. It is also an advantage that software components of the smartphone 2 can be started up when charge in the battery 110 rises above a particular charge threshold. It is a further advantage of this example embodiment that a user of the smartphone 2 can set, for each charge threshold, which software components are notified and which are instructed to shutdown when remaining battery charge drops below each charge threshold.

It is an advantage of the above-described example embodiments that software components that are not related to a telephony functionality (for example comprising making and receiving telephone calls, and sending and receiving SMS messages) can adjust their operation on receipt of notifications from the SSM 210, in order to reduce their charge demand on the battery 110. In the above example embodiments, such software components can adjust their operation when battery charge becomes low thereby causing non-telephony functionalities of the smartphone 2 to operate with reduced capabilities. For example, a back-lit display could run at reduced brightness at less than a ‘normal’ charge risk state. Also, such software components could cease operation when battery charge becomes very low. For example, the back-lit display of the previous example could operate with no back light at less than a ‘medium’ charge risk state.

It is another advantage of the above-described example embodiments that software components can also be notified of a change in the CRP value when battery charge rises above a charge threshold. Considering the previous example, the back light of the back-lit display could be restored to a reduced brightness level above a ‘medium’ risk charge state, and restored to full brightness above a low' risk charge state. According to this operation, capabilities of the smartphone 2 which are limited when battery charge is low are automatically restored when battery charge increases above a predefined level. Such an operation could for example be particularly advantageous when an internet download is halted before completion due to low power, as in this case, the download is automatically completed as soon as the battery is recharged above the predefined level.

It is within the scope of some example embodiments that the software components to be notified, shutdown or started up when the various charge thresholds are crossed may be hard coded, and/or may also be user-specified, such as, for example, via a graphical user interface. With reference to the example embodiment of FIG. 3, if software components to be notified are user-specified, the SSM 210 also provides a graphical user interface for receiving the user's specified preferences. This graphical user interface may be the same as the one depicted in FIG. 7 however, the box 408 would not be present.

Further, it is also within the scope of some example embodiments that the quantity of remaining battery charge corresponding to each charge threshold (or charge risk state) may be specified by a user. In such example embodiments, the user is able to set the charge threshold values. For example, the graphical user interface of FIG. 7 is modified to provide a nested box against each charge risk state within the box 402. Each nested box is configured to receive a number between 0 and 100, wherein 0 represents an empty battery and 100 represents a full battery. The value input to each nested box indicates the upper limit of the charge risk state which corresponds to the box. In other words, the value indicates the charge threshold value relating to the state to which the box relates. For example, if the value ‘12’ was input for a box relating to a charge risk state ‘high’, when the remaining charge in the battery is above 12 the charge risk state is said to be ‘medium’, whereas below 12 the charge risk state is said to be ‘high’. Furthermore, the ‘high’ charge threshold would be said to be ‘12’.

The example embodiments discussed above have been described with reference to the notification, shutdown and start up of software components of the smartphone 2. It is within the scope of some example embodiments that the term ‘software component’ includes both software applications and software frameworks. An advantage of notifying or shutting down software frameworks rather than software applications is that once a framework has been notified or instructed to shutdown, it can handle the notification or shutdown of all applications beneath it, in a centralised and controlled manner. In particular, the order in which applications are shutdown can be chosen according to inter-dependencies between individual software applications. Therefore, a software application may be shutdown after all software applications which are dependent on that software application have been shutdown first. This may assist in retaining the integrity of the device and avoiding a fail state.

Additionally, it is within the scope of some example embodiments that hardware components, in addition to, or instead of, software components can be notified, shutdown or started up when a charge threshold is crossed. As hardware components of the device also draw charge from the battery 110 in order to operate, further charge savings could be made by requesting certain hardware components to limit or cease their operation. When conserving battery charge to prolong the period of time during which telephony functions can be performed, hardware which is not used to perform telephony functions may be notified or shutdown. For example, the GPS receiver and antenna 11 is a hardware component which is not used by the smartphone 2 to perform a telephony function and therefore, this hardware component could be shutdown early in the charge conservation process, for example when the charge risk state changes from a ‘normal’ state to a ‘low’ state. It is noted that the notification and shutdown of software components may frequently be related to, and involve, the operation of certain hardware components. More specifically, with reference to the previously mentioned example of instructing a software component responsible for controlling a back-lit display, this example involved adjusting the software component's operation in order to cause battery charge savings resulting from an adjustment in the behaviour of the back-lit display hardware. Therefore, although the charge conservation system adjusted the software component, the possible charge savings were caused by the hardware component controlled by the software component.

Finally, various additions and modifications may be made to the above described example embodiments to provide further example embodiments, apparent to the intended reader being a person skilled in the art, any and all of which are intended to fall within the scope of the appended claims. For example, features from any of the above described example embodiments may be combined together to generate further embodiments of the present invention.

What is claimed is:

1. A method, comprising:
determining a remaining electrical charge in a battery of an apparatus using a charge conserving system of the apparatus, said apparatus comprising a plurality of hardware or software components, said charge conserving system being capable of defining one or a number of charge thresholds, the or each charge threshold corresponding to a quantity of remaining electrical charge in the battery, and
broadcasting a charge status notification, using the charge conserving system, to at least one of a predefined group of the hardware or software components when the remaining electrical charge in the battery falls below the or each charge threshold.

2. The method according to claim 1, wherein each charge status notification comprises an indication of a quantity of remaining electrical charge in the battery at a corresponding broadcast time.

3. The method according to claim 1, wherein the charge conserving system defines a plurality of charge thresholds and is capable of broadcasting a charge status notification to a different set of the predefined group when the remaining electrical charge in the battery falls below each different charge threshold.

4. The method according to claim 1, wherein the or each hardware or software components is capable of reducing its electrical charge demand on the battery on receipt of a charge status notification broadcast when the remaining electrical charge in the battery falls below a charge threshold, in order to conserve battery charge.

5. The method according to claim 1, further comprising:
broadcasting a charge state notification, using the charge conserving system, to at least one of the predefined group of the hardware or software components when the remaining electrical charge in the battery rises above the or each charge threshold.

6. The method according to claim 5, wherein the charge conserving system defines a plurality of charge thresholds and is capable of broadcasting a charge status notification to a different set of the predefined group when the remaining electrical charge in the battery rises above each different charge threshold.

7. The method according to claim 5, wherein the or each hardware or software components is capable of increasing its electrical charge demand on the battery on receipt of a charge status notification broadcast when the remaining electrical charge in the battery rises above a charge threshold, in order to restore the apparatus to a previous state of operation.

8. The method according to claim 1, further comprising:
receiving, at the charge conserving system, registration from each hardware or software components, and
defining, using the charge conserving system, at least part of the predefined group in dependence on which hardware or software components it has received registration from.

9. The method according to claim 1, further comprising:
instructing at least one of the predefined group to shutdown when the remaining electrical charge in the battery falls below the or each charge threshold, using a decision engine of the charge conserving system.

10. The method according to claim 9, wherein the charge conserving system defines a plurality of charge thresholds and the decision engine is capable of instructing a different set of the predefined group to shutdown when the remaining electrical charge in the battery falls below each different charge threshold.

11. The method according to claim 9, further comprising:
instructing at least one of the predefined group to start-up when the remaining electrical charge in the battery rises above the or each charge threshold, using the decision engine.

12. The method according to claim 11, wherein the charge conserving system defines a plurality of charge thresholds and the decision engine is capable of instructing a different set of the predefined group to start-up when the remaining electrical charge in the battery rises above each different charge threshold.

13. The method according to claim 12, wherein the charge conserving system broadcasts a charge status notification to at least one hardware or software components when the remaining electrical charge in the battery crosses one of the plurality of charge thresholds, and the decision engine starts-up or shuts-down the at least one hardware or software components when the remaining electrical charge in the battery crosses a different one of the plurality of charge thresholds.

14. The method according to claim 9, wherein the decision engine instructs a hardware or software components to shutdown only if it is not required by the apparatus to perform a telephony function.

15. The method according to claim 1, wherein the charge conserving system is capable of defining at least part of the predefined group in dependence on an input received from a user of the apparatus.

16. The method according to claim 15, wherein the charge conserving system is capable of defining at least part of any set of the predefined group in dependence on an input received from a user of the apparatus.

17. The method according to claim 1, further comprising:
setting the quantity of remaining electrical charge in the battery which corresponds to the or each charge threshold in dependence on an input received from a user of the apparatus, using the charge conservation system.

18. The method according to claim 1, wherein each hardware or software component of the predefined group is not required by the apparatus to perform a telephony function.

19. An apparatus, comprising:
at least one processor; and
at least one memory including computer program code the at least one memory and the computer program code configured to, with the at least one processor, cause the apparatus to perform at least the following:
determine a remaining electrical charge in a battery using a charge conserving system, said charge conserving system being capable of defining one or a number of charge thresholds, the or each charge threshold corresponding to a quantity of remaining electrical charge in the battery, and
broadcast a charge status notification, using the charge conserving system, to at least one of a predefined group of hardware or software components when the remaining electrical charge in the battery falls below the or each charge threshold.

20. A computer program product comprising a computer readable medium bearing computer program code embodied therein for use with a computer, the computer program code comprising:
code for determining a remaining electrical charge in a battery of an apparatus using a charge conserving system, said apparatus comprising a plurality of hardware or software components, said charge conserving system being capable of defining one or a number of charge thresholds, the or each charge threshold corresponding to a quantity of remaining electrical charge in the battery, and
code for broadcasting a charge status notification, using the charge conserving system, to at least one of a predefined group of the hardware or software components when the remaining electrical charge in the battery falls below the or each charge threshold.
